(19) United States
(12) Patent Application Publication
(10) Pub. No.: US 2016/0268963 A1
(43) Pub. Date: Sep. 15, 2016

(54) Method for Delivering Flexible Solar Cells into a Roll-to-Roll Module Assembly Process

(71) Applicant: NUVOSUN, INC., Milpitas, CA (US)

(72) Inventors: Szu-Ting Tsai, San Jose, CA (US); Thomas M. Valeri, Gilroy, CA (US)

(21) Appl. No.: 15/035,621

(22) PCT Filed: Nov. 11, 2014
(86) PCT No.: PCT/US2014/064975

§ 371 Date: May 10, 2016

Related U.S. Application Data
(60) Provisional application No. 61/904,058, filed on Nov. 14, 2013.

(51) Int. Cl. H02S 30/20; H01L 31/0443; H01L 31/05

(52) U.S. Cl. CPC H02S 30/20; H01L 31/0508; H01L 31/0443

(57) ABSTRACT

Methods and systems for forming and packaging a roll of photovoltaic cells are provided. A string of photovoltaic cells is incrementally formed such that the photovoltaic cells in the string extend from a leading edge of the string, where incrementally forming the string comprises sequentially connecting successive photovoltaic cells, and where sequentially connecting successive photovoltaic cells comprises connecting each successive photovoltaic cell to a respective, previously-connected photovoltaic cell that is farthest from the leading edge. Bypass diodes are electrically connected to successive portions of the string as the string is being formed. The string is wound with the bypass diodes connected thereto into a roll by rotating the leading edge of the string about a take-up roller as the string is being formed. In response to the string reaching a second predetermined number of photovoltaic cells, the roll is completed and packaged.

### CROSS-REFERENCE TO RELATED APPLICATION

This application claims priority to U.S. Provisional Application No. 61/904,058, filed Nov. 14, 2013, the disclosure of which is hereby incorporated by reference in its entirety.

### TECHNICAL FIELD

The invention relates to systems and processes for packaging of photovoltaic cells.

### BACKGROUND

In examples, thin film solar cells on flexible substrates include amorphous silicon disposed on a thin metal foil (e.g., stainless steel) and copper indium gallium diselenide (CIGS) on metallic or polyimide foils. Thin film cadmium telluride (CdTe) solar cells may be produced on glass, but may also be produced on a flexible substrate. To be useful in a solar power system, solar cells are electrically interconnected serially with other similar solar cells to raise the voltage levels and minimize losses that would otherwise occur due to high currents.

### SUMMARY

In one aspect, the present disclosure describes a method. The method comprises incrementally forming a string of photovoltaic cells such that the photovoltaic cells in the string extend from a leading edge of the string. Incrementally forming the string comprises sequentially connecting successive photovoltaic cells, and sequentially connecting successive photovoltaic cells comprises connecting each successive photovoltaic cell to a respective, previously-connected photovoltaic cell that is farthest from the leading edge. The method also comprises electrically connecting bypass diodes to successive portions of the string as the string is being formed, such that each successive portion includes a bypass diode connected in parallel with a first predetermined number of photovoltaic cells connected in series. The method further comprise winding the string with the bypass diodes connected thereto into a roll by rotating the leading edge of the string about a take-up roller as the string is being formed. The method also comprises completing the roll in response to the string reaching a second predetermined number of photovoltaic cells; and packaging the completed roll.

In another aspect, the present disclosure describes a system. The system comprises a fabrication apparatus configured to incrementally form a string of photovoltaic cells such that the photovoltaic cells in the string extend from a leading edge of the string. To incrementally form the string, the fabrication apparatus is configured to sequentially connect successive photovoltaic cells, and, to sequentially connect successive photovoltaic cells, the fabrication apparatus is configured to connect each successive photovoltaic cell to a respective, previously-connected photovoltaic cell that is farthest from the leading edge. The fabrication apparatus is further configured to optionally electrically connect bypass diodes to successive portions of the string as the string is being formed, such that each successive portion includes a bypass diode connected in parallel with a first predetermined number of photovoltaic cells connected in series. The system also comprises a rolling apparatus configured to wind the string with the bypass diodes connected thereto into a roll by rotating the leading edge of the string about a take-up roller as the string is being formed, and complete the roll in response to the string reaching a second predetermined number of photovoltaic cells. The system further comprises a packaging apparatus configured to package the completed roll.

In still another aspect, the present disclosure describes a package. The package includes a roll of photovoltaic cells. The roll of photovoltaic cells comprises a string of photovoltaic cells wound around a core. The string of photovoltaic cells can be a single string per roll or can comprise groups of photovoltaic cells separated by respective separating regions, where each group comprises a predetermined number of photovoltaic cells connected in series, and where each separating region electrically isolates the photovoltaic cells in one group from the photovoltaic cells in an adjacent group. The package also includes a packaging that at least partially surrounds the roll of photovoltaic cells.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 illustrates geometry of a section of a flat metallic mesh, in accordance with an example embodiment.

FIGS. 2a and 2b illustrate a finished photovoltaic cell, in accordance with an example embodiment.

FIG. 3a illustrates a schematic planar view from a light-sensitive side of a portion of a long interconnected string of flexible photovoltaic cells, in accordance with an example embodiment.

FIG. 3b illustrates a schematic cross-sectional side view of the portion of interconnected cells of FIG. 3a, in accordance with an example embodiment.

FIG. 4 is a flow chart illustrating a method for packaging photovoltaic cells, in accordance with an example embodiment.

FIG. 5 illustrates a string build tool with sequentially connected photovoltaic cells, in accordance with an example embodiment.

FIG. 6a illustrates operation of a blocking diode, in accordance with an example embodiment.

FIG. 6b illustrates operation of a bypass diode, in accordance with an example embodiment.

FIG. 7a illustrates a bypass diode connected to a group of photovoltaic cells, in accordance with an example embodiment.

FIG. 7b illustrates two bypass diodes connected to two successive groups of photovoltaic cells, in accordance with an example embodiment.

FIG. 8 illustrates feeding a string of photovoltaic cells to a take-up roller, in accordance with an example embodiment.

FIG. 9 illustrates a completed roll and packaging for the completed roll, in accordance with an example embodiment.

### DETAILED DESCRIPTION

The following detailed description describes various features and functions of the disclosed systems and methods with reference to the accompanying figures. In the figures, similar symbols identify similar components, unless context dictates otherwise. The illustrative system and method embodiments described herein are not meant to be limiting. It may be readily understood that certain aspects of the disclosed systems and methods can be arranged and combined in a wide variety of different configurations, all of which are contemplated herein.

The terms “photovoltaic cell” (also “solar cell” herein), as used herein, generally refers to a device comprising a photoactive material (or absorber) that is configured to generate electrons (or electricity) upon exposure of the device to electromagnetic radiation (or energy), or a given wavelength or distribution of wavelengths of electromagnetic radiation. A photovoltaic device can include a flexible substrate adjacent to the photoactive material. The term “photovoltaic string,” as used herein, generally refers to a device comprising one or more photovoltaic cells.

Solar cells may be electrically connected in series with other similar solar cells to raise the voltage levels and minimize resistive losses that would otherwise occur due to high currents. The number of serially-connected cells may be restricted in installations based on voltage limitations defined by electrical standards (UL or TUV), but still some applications involve a large number of serially-connected solar cells. For instance, roofing applications may use a large number of cells integrated into solar modules that are several meters long. In some examples, cells can be shipped to a roofing supplier as boxes of several hundred individual units for layup at the supplier facility; however, such shipping method may involve both significant capital investment and labor requirements at the supplier site. In other examples, strings of cells that are several meters long can be pre-made, but shipping and handling such strings may be complex.

Other handling problems may also arise. For example, individual cells are fragile and can be damaged during handling and shipping. Long strings of cells that are several meters long may be cumbersome to handle and several people may be involved in handling such strings, which may add complexities for packaging and shipping. Further, if individual cells are sent to a customer, the customer may install bypass diodes to groups of cells for protection, which also may involve labor and capital investments. Also, solar cell application may involve multiple sizes of strings based on type of application. Having to integrate individual cells into different size of strings at the customer supplier to match different applications may be cumbersome.

Disclosed herein are methods and systems for packaging and shipping photovoltaic cells that alleviate the aforementioned problems. A string of photovoltaic cells can be formed, wound into a roll, and packaged. The packaged roll can include any number of photovoltaic cells (e.g., thousands). The packaged roll can facilitate shipping to and handling by a customer. For example, the roll of cells can be unwound and handled by a single person at the customer's facility. Bypass diodes may be integrated into the roll instead of being added at the customer's facility. The roll of cells may be appropriate for custom size applications. A portion of the roll including a predetermined number of cells suitable for a particular application may be unwound and cut from the rest of the roll to be used for a particular application. Additional aspects and advantages will become readily apparent from the methods and systems disclosed herein.

### I. Photovoltaic Cell Construction

In some examples, a photovoltaic cell comprises a photovoltaic device that includes a flexible substrate adjacent to a photoactive material and an interconnect from an electrode of a first cell to an electrode of an adjacent cell. For example, the interconnect may include wires, a metallic mesh, etc. adjacent to the photovoltaic device. The photovoltaic device can include a flexible thin film photovoltaic device. The metallic mesh may comprise a plurality of holes (or openings) for permitting electromagnetic radiation to come in contact with the photoactive material. The photovoltaic cell can further comprise an electrically insulating material disposed between the metallic mesh and the photovoltaic device at an edge portion of the photovoltaic device. In example, the electrically insulating material can be optically transparent.

An opening of the metallic mesh can have any shape, size, or configuration. An opening can have a circular, triangular, square, rectangular, pentagonal, hexagonal, heptagonal, octagonal, or nonagonal, or any partial shape (e.g., semi-circular) or combination thereof

The photoactive material may be configured to absorb light and generate electrons upon exposure to electromagnetic radiation (or light). The metallic mesh can be adapted to collect and conduct electrons out of the photovoltaic device and to a load, such as, for example, an energy storage system (e.g., battery), an electrical grid, or an electronic device or system. The photoactive material can be formed of various materials. Examples of flexible photoactive materials include, without limitation, amorphous silicon, copper chalcogenides (e.g., copper indium sulfides, copper indium selenides, copper indium gallium diselenide or CIGS, etc.), cadmium telluride (CdTe) and CdZnTe/CdTe.

In some cases, the photovoltaic cell further comprises an optically transparent film that secures the metallic mesh to the photovoltaic device. The optically transparent film can be a pressure-sensitive adhesive. As an alternative, the metallic mesh can be secured to the photovoltaic device by a conductive epoxy. As another alternative, the metallic mesh can be attached to the photovoltaic device by a low melting point solder. As still other alternatives, the metallic mesh can be attached or secured to the photovoltaic device by a conductive tape or thermoplastic materials such as hot melt adhesives.

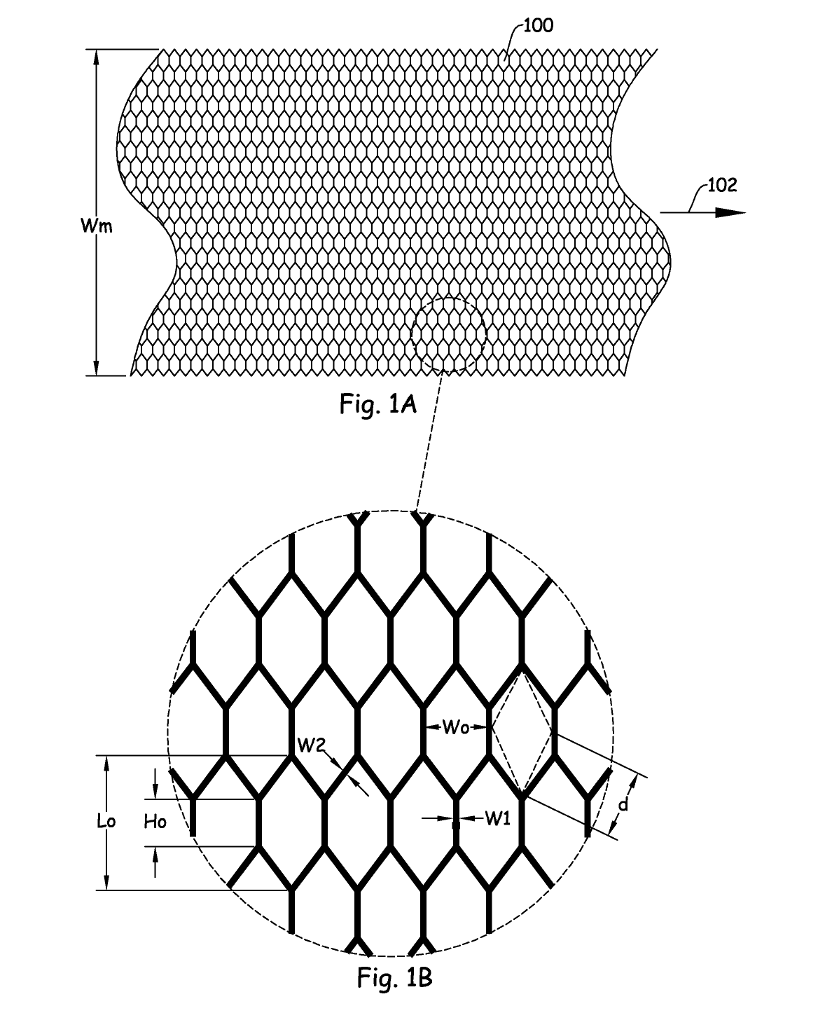

FIG. 1 illustrates geometry of a section of a flat metallic mesh, in accordance with an example embodiment. Metallic mesh 100 can be mounted on a photovoltaic device to form a photovoltaic cell. The mesh 100 has width Wm and may have a substantially long length in the direction of arrow 102. Expanded view 104 illustrates the details of the mesh geometry. In general an opening in the mesh has a width Wo, a length Lo, and a side height Ho. In one example, Ho can be on the order of ⅓ to ½ of Lo, so the opening resembles an elongated hexagon, but Ho can be zero. In that example, the mesh opening takes the form of a diamond (dashed lines) with sides of length d. If the expansion of the metal is continued until Wo is equal to Lo, then the openings can be more symmetrical, and if Ho also approaches zero the diamonds can be squares.

The mesh 100 can be formed of a metallic material, such as copper, iron, tin, nickel, gold, silver, platinum, palladium, chromium, tungsten, titanium, tantalum, or any combination thereof. In some examples, the mesh 100 can be formed of a polymeric material and coated with a metallic material.

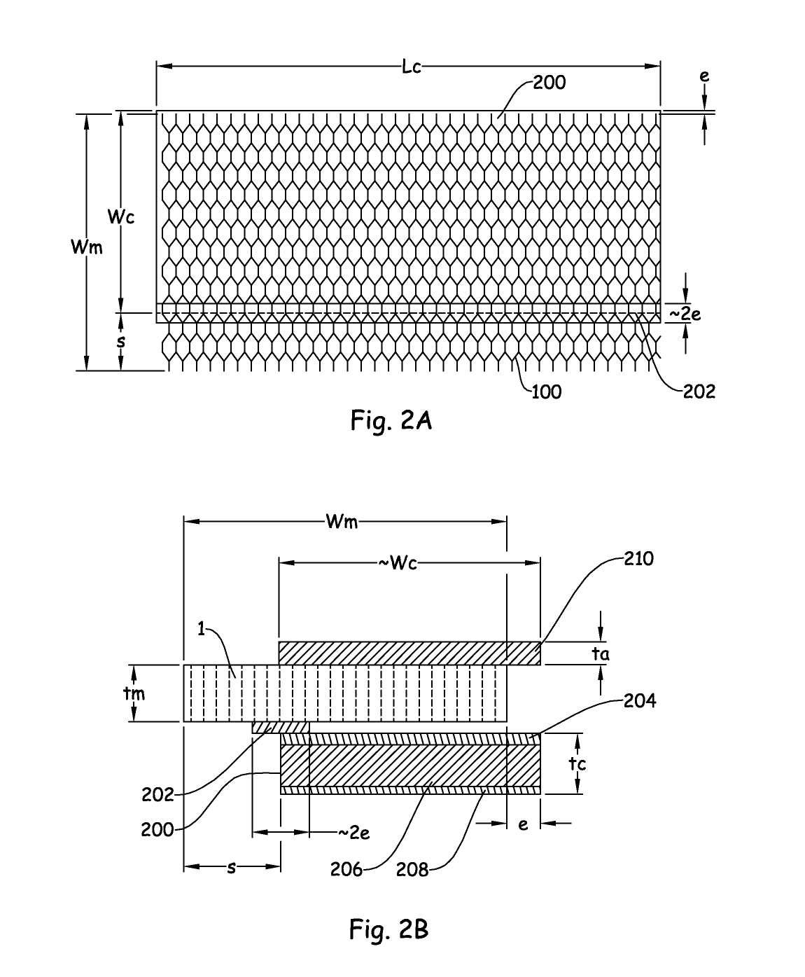

FIGS. 2a and 2b illustrate a finished photovoltaic cell, in accordance with an example embodiment. A planar view of an individual photovoltaic cell is shown in FIG. 2a. The active photovoltaic (or solar) device 200 (also “device” herein) has width We and length Lc. A section of the mesh 100 with width Wm as shown in FIG. 1 can be applied over device 200. The mesh 100 extends (i.e., overhangs) over one edge of the device 200. On a left side of the device 200 the mesh 100 is short (from an edge of the device 200) by an amount “e.” The mesh 100 overlaps one long side of the device 200 by an amount “s” which can be a few multiples Lo, for example. The mesh 100 could cause electrical shorts or shunts at the edge of the device 200 along the overhang region. This may be prevented by the prior application of a thin strip 202 of insulating transparent pressure-sensitive adhesive (PSA) of width approximately 2e. The mesh 100 can be attached to the device 200 by way of a securing member, such as PSA, a temperature-sensitive transparent tape, or a hot melt adhesive whose size can be about the same as that of the mesh minus the overhang region “s.”

FIG. 2b illustrates a schematic diagram of the cross section of the photovoltaic cell of FIG. 2a. The photovoltaic device 200 may include at least three parts: a photoactive cell (or material) 204, an electrically conductive flexible substrate 206, and, in some cases, a reverse side coating 208. Total thickness of the photoactive cell 204 can be on the order of a few nanometers to micrometers. The substrate 206 can be formed of stainless steel or other metallic foil. The substrate 206 can be electrically conductive and may serve as an extension of the back electrode of the photoactive cell 204. The reverse side coating 208 may include a thin metal coating used to provide galvanic compatibility with the mesh interconnection between adjacent cells. As an example, the mesh 100 could be made from copper and plated with a thin coating of tin. In such a case, the coating 208 could be made of tin, although the structure could function for an extended period of time without coating 208 under optimal environmental packaging conditions, such as, for example, if the cell is packaged under vacuum or in an inert (e.g., Ar, He) environment. The flexible photovoltaic device 200 has a thickness tc that is dependent on the thickness of each of the cell 204, the substrate 206 and the coating 208.

The transparent insulating strip 22 applied along the edge of one long side of the device 200 can prevent the overhanging area “s” of the mesh 100 from causing shunts along the edge of the device 200. The thickness tm of the mesh 100 can be varied to obtain adequately low electrical resistance while minimizing shading loss. The mesh 100 can be held against the device 200 by transparent tape 210 (e.g., PSA or hot melt adhesive). In FIG. 2b on the edge where the mesh 100 does not overhang the device 200, tape 210 is shown overhanging the edge of the mesh 100 by a distance e; however, in some examples, the tape can cover the mesh 100 on this side, but not extend past the edge of the device 200 on either side.

### II. Forming a String of Cells

In some cases, a photovoltaic string may comprise a plurality of photovoltaic cells. The plurality of photovoltaic cells can be in electrical contact with one another in series (i.e., serial configuration). In some examples, a metallic mesh of one photovoltaic cell is in electrical contact with an underside (back side opposite to the light-receiving side of the photovoltaic device) of an adjacent photovoltaic cell. Photovoltaic cells can be disposed adjacent to one another in a “string” of photovoltaic cells.

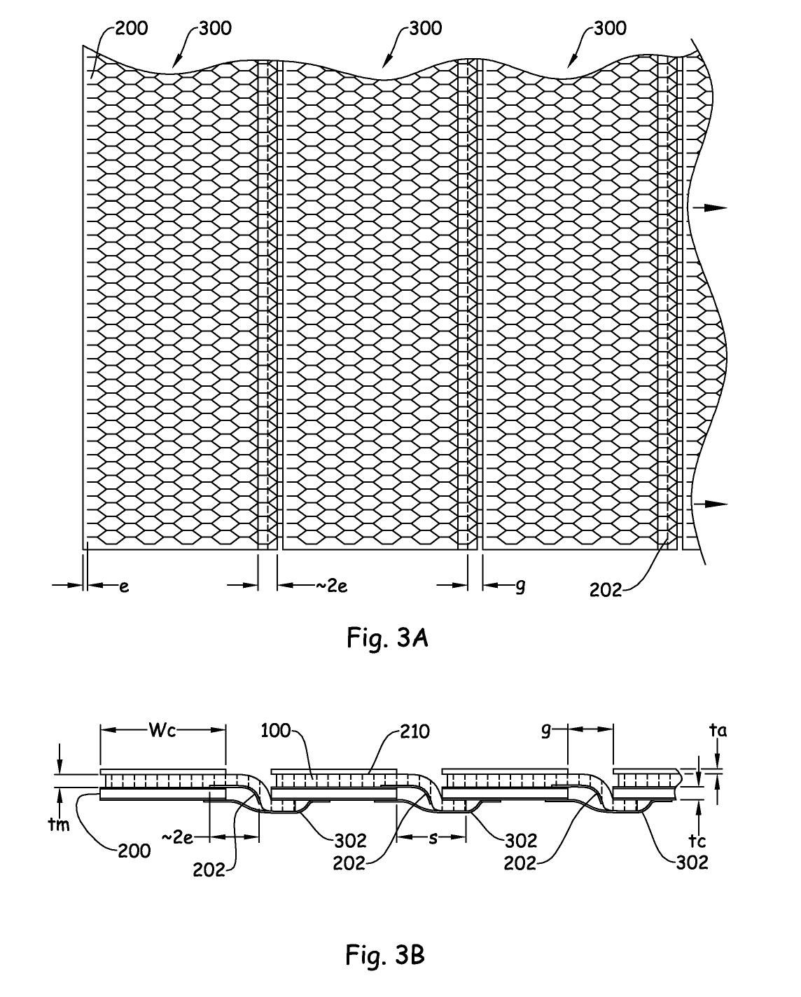

FIG. 3a illustrates a schematic planar view from a light-facing side of a portion of a long interconnected string of flexible photovoltaic cells 300, in accordance with an example embodiment. Each photovoltaic cell can include the mesh 100, the photovoltaic device 200, and insulating strip 202. The individual photovoltaic cells 300 are separated by a gap “g.”

FIG. 3b illustrates a schematic cross-sectional side view of the portion of interconnected cells 300 of FIG. 3a, in accordance with an example embodiment. In an example, a second cell is placed on an overhang region “s” of the mesh 100 of a first cell with a gap “g” between the cells. A relatively wide strip of a coupling member (e.g., PSA or hot melt adhesive) 302 holds two adjacent cells together without disrupting an electrical connection between a mesh of the first cell and a back portion (e.g., portion facing away from light) of the second cell. In an example, the couple member 302 could be placed to bridge the first cell to the second cell. In another example, the couple member 302 could be placed on the second cell only. The insulating strip 202 may be configured to prevent the edge of the first cell from coming in contact with (and, e.g., being shunted by) the bent over mesh. In some cases, the insulating strip 202 may be configured to prevent the mesh 100 from shorting a top (light receiving) portion of a given cell with a bottom portion of an adjacent cell, such as when adjacent devices or cells 200 are brought laterally towards one another to form a photovoltaic string. Strings of cells of a given length can be made in such fashion, and can be handled as a unit.

### III. Example Methods and Systems for Packaging Photovoltaic Cells

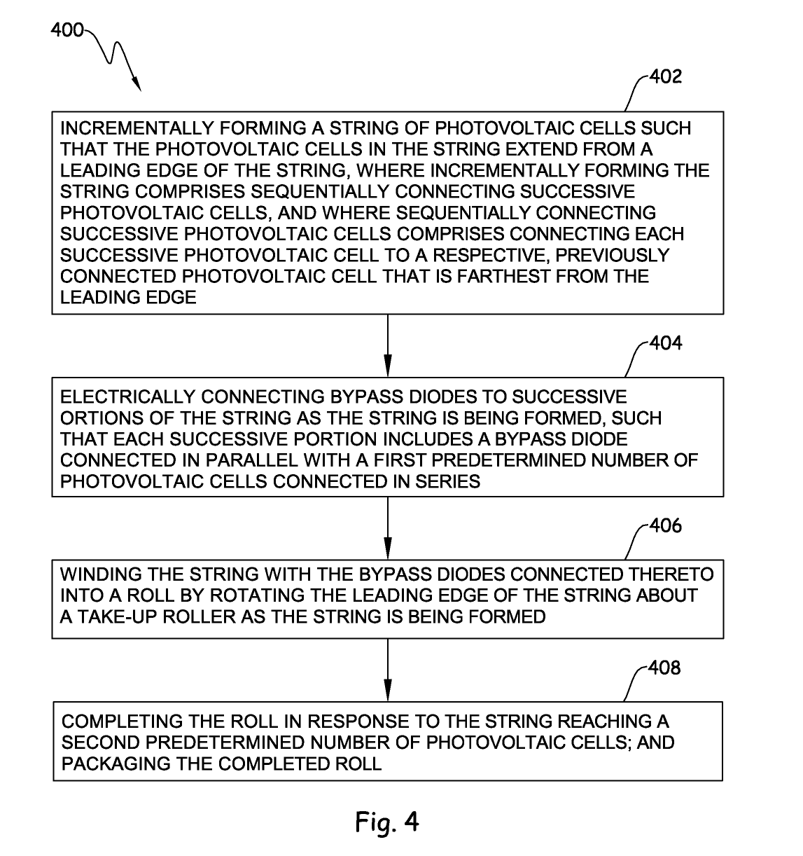

FIG. 4 is a flow chart illustrating a method 400 for packaging photovoltaic cells, in accordance with an example embodiment. The method 400 may be implemented by a computer system (e.g., including robotic systems) having one or more computer processors that are programmed to implement the method 400. The method 400 may include one or more operations, functions, or actions as illustrated by one or more of blocks 402-408. Although the blocks are illustrated in a sequential order, these blocks may in some instances be performed in parallel, and/or in a different order than those described herein. Also, the various blocks may be combined into fewer blocks, divided into additional blocks, and/or removed based upon the desired implementation.

At block 402, the method 400 includes incrementally forming a string of photovoltaic cells such that the photovoltaic cells in the string extend from a leading edge of the string. Incrementally forming the string comprises sequentially connecting successive photovoltaic cells. Sequentially connecting successive photovoltaic cells comprises connecting each successive photovoltaic cell to a respective, previously-connected photovoltaic cell that is farthest from the leading edge.

In an example, a computing system may be configured to cause a robot or a robot arm to pick a first cell, with the light-receiving side facing down, and load the cell into an input side of a string build tool. The computing system may be configured, via the robot for example, to move or index the first cell to a location of a next cell and load a second cell onto the string build tool in the place where the first cell was initially loaded. The robot may be configured to load the second cell such there is a gap (e.g., 1 mm) between the two cells and an overhanging mesh of the second cell may be connected to the back side (opposite the light-sensitive side) of the first cell. For example, the computing system may be configured to include and use a robotic vision system to achieve a high level of accuracy in indexing the cells in respective appropriate locations, maintaining gaps, and performing any handling operation for the cells.

Further, a piece of pressure-sensitive or melt-adhesive tape may be applied to secure the overhang mesh of the second cell to the back side of the first cell. The pressure-sensitive tape may be of a given length (e.g., the same length of the cell), and can be either conductive or non-conductive. This process may be repeated to sequentially connecting successive photovoltaic cells by connecting each successive photovoltaic cell to a respective, previously-connected photovoltaic cell that is farthest from the leading edge (edge of the first cell to be loaded).

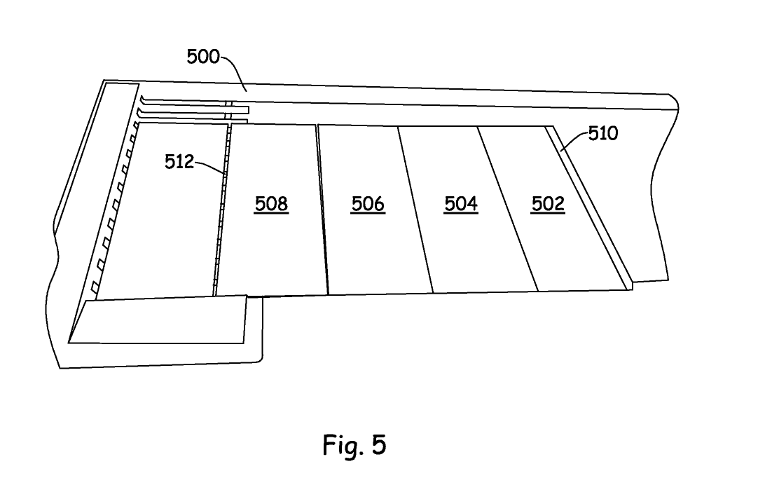

FIG. 5 illustrates a string build tool 500 with sequentially connected photovoltaic cells, in accordance with an example embodiment. FIG. 5 depicts a first cell 502 that may have been loaded first to the string build tool 500. Cells 504, 506, and 508 may have been sequentially loaded and successively connected to form the string of photovoltaic cells. An edge of the first cell 502 forms a leading edge 510 of the string. The computing system may be configured to cause (e.g., via the robot) the cells to move down stream while cells are sequentially added to a farthest end 512 from the leading edge 510.

Referring back to FIG. 4, at block 404, the method 400 includes electrically connecting bypass diodes to successive portions of the string as the string is being formed, such that each successive portion includes a bypass diode connected in parallel with a first predetermined number of photovoltaic cells connected in series. A diode uses a semiconductor material (e.g., silicon) and has two terminals. A given diode is configured to allow electricity to pass in one direction but not the other.

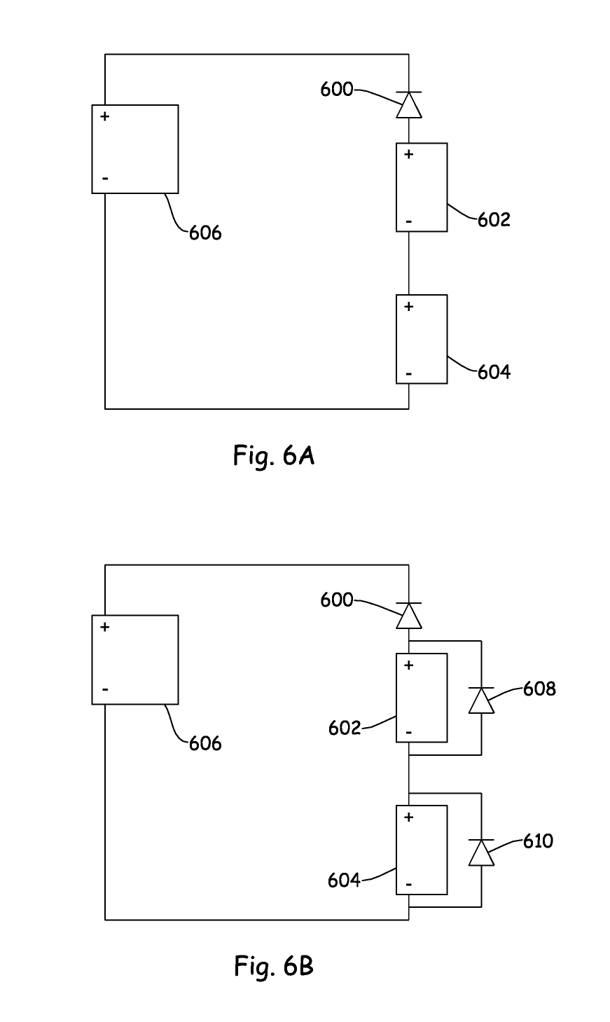

FIG. 6a illustrates operation of a blocking diode 600, in accordance with an example embodiment. FIG. 6a depicts an example setup with two solar cell modules (strings or panels) 602 and 604 charging a battery 606 (for simplicity no controller is shown) with the blocking diode 600 in series with the two modules, which are also connected in series. Each module may include a single solar cell or a group of a predetermined number of cells. When light is projected on the panels, as long as the voltage produced by the two modules 602 and 604 is greater than that of the battery 606, charging the battery 606 will take place. However, when there is no light projected on the modules 602 and 604 (i.e., in a dark environment), no voltage will be produced by the modules 602 and 604, and the voltage of the battery 606 would cause a current to flow in the opposite direction through the modules 602 and 604, discharging the battery 606. The blocking diode 600 prevents such discharging. In some examples, blocking diodes may be integrated into construction of solar modules so further blocking diodes are not required at a customer's facility.

FIG. 6b illustrates operation of bypass diodes 608 and 610, in accordance with an example embodiment. As shown, bypass diodes 608 and 610 are connected in parallel with modules 602 and 604, respectively. In some cases, one of the modules 602 and 604 shown in FIG. 6a or 6b may be shaded (or damaged), while other modules may be subjected to light. Shading of part of a module may be caused by a tree branch, debris, or snow. In these cases, the shaded module may not produce any significant power, and may have a high resistance, blocking the flow of power produced by un-shaded modules. Bypass diodes 608 and 610 alleviate this problem. Electric current produced by the un-shaded module can flow through a bypass diode to avoid the high resistance of the shaded module. For example, if the module 602 is shaded and causes a high resistance, current produced by the module 604 can bypass the module 602 and flow through the bypass diode 608 instead.

In some applications, solar panels are constructed with the cells divided into groups (modules), each group having a built-in bypass diode. At block 404 of the method 400, after a portion of the string containing a predetermined number of cells is formed, a bypass diode may be electrically connected in parallel to the photovoltaic cells of the portion. For instance, each bypass diode may have an anode electrically connected to a cathode of one photovoltaic cell in the portion of the string and has a cathode electrically connected to an anode of another photovoltaic cell in the portion of the string. The bypass diode may further be bonded (e.g., using an epoxy material) to the photovoltaic cells.

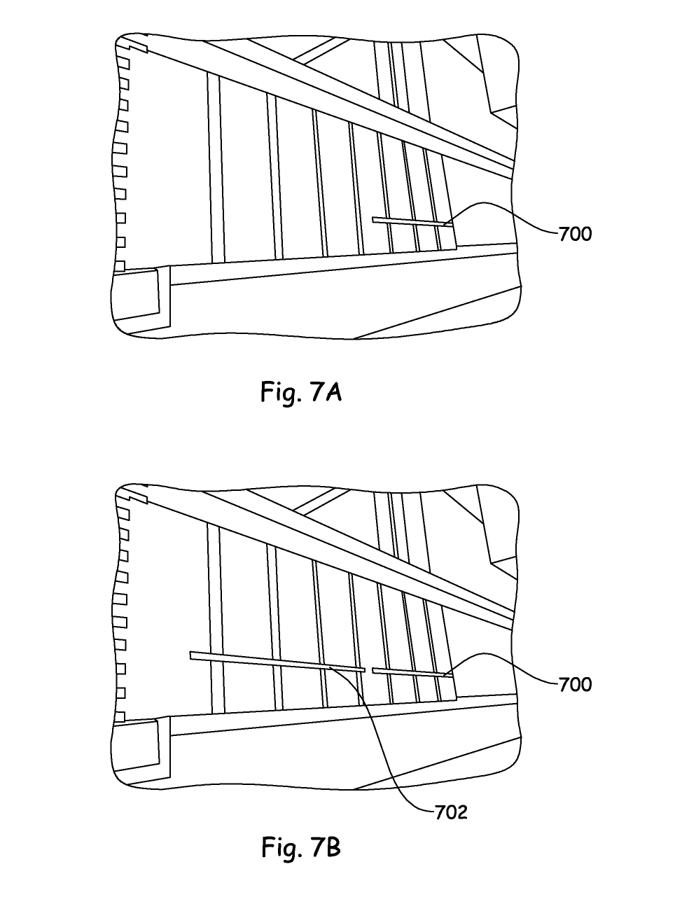

FIG. 7a illustrates a bypass diode connected to a group of photovoltaic cells, in accordance with an example embodiment. FIG. 7a depicts a bypass diode 700 connected in parallel to a number of serially-connected photovoltaic cells in the string. FIG. 7b illustrates two bypass diodes connected to two successive groups of photovoltaic cells, in accordance with an example embodiment. Bypass diodes may be added to the string as each group of photovoltaic cells is formed. FIG. 7b depicts bypass diodes 700 and 702 connected to respective group of cells.

Referring back to FIG. 4, at block 406, the method 400 includes winding the string with the bypass diodes connected thereto into a roll by rotating the leading edge of the string about a take-up roller as the string is being formed. The computing/robotic system may be configured to maintain adding and serially connecting photovoltaic cells to respective, previously-connected cells. When the string reaches a certain length, the leading edge (e.g., the leading edge 502 in FIG. 5) may be fed to a take-up roller, which may be configured to rotate at a given speed to wind the string into a roll as the string is being formed.

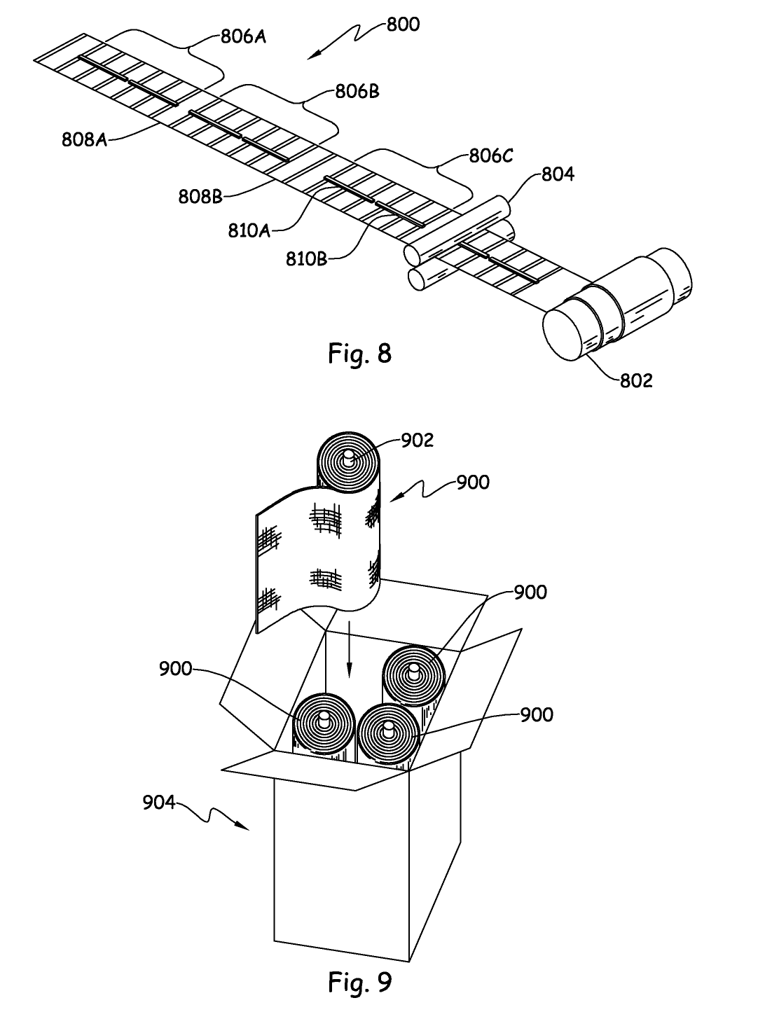

FIG. 8 illustrates feeding a string of photovoltaic cells 800 to a take-up roller 802, in accordance with an example embodiment. FIG. 8 depicts the string 800 being fed to the take-up roller 802 as the string 800 is being formed. The take-up roller 802 may include a core, on which the string is rolled, that is made of an appropriate material. In some examples, the string may be fed through a roll laminator 804 before the string reaches the take-up roller 802. The roll laminator 804 may be configured to rotate at a given rotational speed that matches a respective rotational speed of the take-up roller 802 and is also equivalent to linear speed of cells moving on the string build tool as a result of cells being added to the string. As an example, the roll laminator 804 may apply a pressure (e.g., 20 psi) to enhance adhesion of a pressure-sensitive tape (e.g., the piece of pressure-sensitive tape described at block 402) to the back of a given cell. Heat may or may not be used in addition to the pressure of the roller laminator 804. Using the roll laminator 804 as a means for applying pressure and/or heat is an example for illustration only, and other techniques can be used to apply such pressure to enhance adhesion of the pressure-sensitive tape to the back of a given cell.

After the string 800 is fed through the roll laminator 804, the string 800 is fed to the take-up roller 802, which is configured to rotate at substantially the same speed as roll laminator 804. Tension force between the roll laminator 804 and take-up roller may be determined in a manner that helps keep winding the string 800 straight onto the core of the take-up roller 802.

FIG. 8 also depicts the string 800 divided into groups of cells such as groups 806A, 806B, and 806C separated by respective separating regions 808A and 808B. FIG. 8 also shows bypass diodes such as bypass diodes 810A and 810B connected in parallel a predetermined number of photovoltaic cells forming portions of the string. The photovoltaic cells of each group of the groups 806A-806C may be electrically connected in series within each group, and each separating region 808A-808B may be configured to electrically isolate the photovoltaic cells in one group from the photovoltaic cells in an adjacent group. For example, each separating region such as 808A and 808B may include electrically-insulating material so as to mechanically connect two adjacent groups of cells without electrically connecting them. In some examples, the groups 806A-806C may include the same number of photovoltaic cells and bypass diodes. In other examples, each group may include a different number of photovoltaic cells and/or a different number of bypass diodes. Such construction may facilitate using the roll of cells for custom size applications. A single roll may include a large number of cells (e.g., 1,000-20,000) but may be divided by separating regions into various groups having different sizes and may be used for several applications requiring the different sizes.

Referring back to FIG. 4, at block 408, the method 400 includes completing the roll in response to the string reaching a second predetermined number of photovoltaic cells; and packaging the completed roll. When a certain number of cells is reached (e.g., 1,000 cells to 20,000 cells based on customer needs), the computing system or robot may be configured to stop adding photovoltaic cells to the string. Further, the roll of cells may be unloaded along with the core to be packaged.

Any type of packages and packaging devices that is suitable for and surrounds, at least partially, the roll of photovoltaic cells can be used. As an example, the roll of photovoltaic cells may be wound around a core made of cardboard or aluminum. In one example, two metal core guards may be mounted on both ends of the core. Diameter of the core guards may be, for example, 2″ wider than the outer diameter of the roll of cells. In an example, upon completing the roll of cells, a piece of foam (e.g., ½″ thick) may be placed all around the outer diameter of the roll in between of the two core guards to protect the photovoltaic cells. The roll of cells may then be placed in a vacuum sealed moisture barrier bag with desiccant. The roll may be further placed into a cardboard box to be ready for shipping. A new core may be loaded onto the take-up roller 802 for a next roll of photovoltaic cells to be produced.

FIG. 9 illustrates a completed roll 900 and a packaging 904 for the completed roll 900, in accordance with an example embodiment. The complete roll 900 is wound around a core 902. As shown in FIG. 9, a plurality of completed rolls can be packaged in a single package 904. However, in some examples, each individual roll can be packaged separately.

In this manner, thousands of cells composing a string can be packaged into a roll. The roll of cells facilitates packaging and handling. The roll of cells can be unwound and handled by a single person at a customer's facility. The bypass diodes are integrated into the roll, and thus no extra labor is required at the customer's facility to install the diodes. The roll of cells is appropriate for custom size applications. A portion of the roll including a predetermined number of cells suitable for a particular application may be unrolled or unwound and cut from the rest of the roll to be used for a particular application. To facilitate such customization, groups of cells may be electrically isolated by separating regions as shown in FIG. 8. By cutting through a separating region, one group of cells can be physically separated from an adjacent group of cells, without damaging the cells in either group.

As described above a robotic system (e.g., a custom-built robotic systems) can be used for manipulating cells in such operations described with respect to the method 400 and FIGS. 1-8. An example system may include sequential modules or apparatuses including a fabrication apparatus, a rolling apparatus, and a packaging apparatus. For example, the fabrication apparatus may be configured to incrementally form the string of photovoltaic cells, and electrically connect the bypass diodes to successive portions of the string as the string is being formed. The rolling apparatus may be configured to wind the string with the bypass diodes connected thereto into a roll by rotating the leading edge of the string about a take-up roller as the string is being formed; and complete the roll when the string reaches a predetermined number of photovoltaic cells. The packaging apparatus may be configured to package the completed roll into a suitable package.

While the present method and/or apparatus has been described with reference to certain implementations, it will be understood by those skilled in the art that various changes may be made and equivalents may be substituted without departing from the scope of the present method and/or apparatus. In addition, many modifications may be made to adapt a particular situation or material to the teachings of the present disclosure without departing from its scope. Therefore, it is intended that the present method and/or apparatus not be limited to the particular implementations disclosed, but that the present method and/or apparatus will include all implementations falling within the scope of the appended claims.

1. A method comprising:
incrementally forming a string of photovoltaic cells such that the photovoltaic cells in the string extend from a leading edge of the string, wherein incrementally forming the string comprises sequentially connecting successive photovoltaic cells, and wherein sequentially connecting successive photovoltaic cells comprises connecting each successive photovoltaic cell to a respective, previously-connected photovoltaic cell that is farthest from the leading edge;
electrically connecting bypass diodes to successive portions of the string as the string is being formed, such that each successive portion includes a bypass diode connected in parallel with a first predetermined number of photovoltaic cells connected in series;
winding the string with the bypass diodes connected thereto into a roll by rotating the leading edge of the string about a take-up roller as the string is being formed;
completing the roll in response to the string reaching a second predetermined number of photovoltaic cells; and
packaging the completed roll.

2. The method of claim 1, wherein connecting each successive photovoltaic cell to a previously-connected photovoltaic cell that is farthest from the leading edge comprises:
electrically connecting each successive photovoltaic cell to the respective, previously-connected photovoltaic cell via a respective metallic mesh.

3. The method of claim 2, wherein each photovoltaic cell in the string has a light-sensitive side and a back side opposite the light-sensitive side, and wherein each metallic mesh in the string has a first portion attached to the light-sensitive side of one photovoltaic cell and has a second portion attached to the back side of another photovoltaic cell.

4. The method of claim 3, wherein the second portion of each metallic mesh has a pressure-sensitive or a melt-adhesive tape disposed thereon, and wherein electrically connecting each successive photovoltaic cell to the respective, previously-connected photovoltaic cell via a respective metallic mesh comprises pressing the back side of each successive photovoltaic cell against the pressure-sensitive tape disposed on the respective metallic mesh.

5. The method of claim 1, wherein the packaging step comprises vacuum sealing the completed roll within a moisture barrier.

6. The method of claim 5, wherein electrically connecting each successive photovoltaic cell to the respective, previously-connected photovoltaic cell via a respective metallic mesh comprises:
applying an optically transparent adhesive to secure the respective metallic mesh to the light-receiving surface of the respective, previously-connected photovoltaic cell.

7. The method of claim 1, wherein the string of photovoltaic cells comprises groups of photovoltaic cells separated by respective separating regions, wherein the photovoltaic cells are electrically connected in series within each group, and wherein each separating region electrically isolates the photovoltaic cells in one group from the photovoltaic cells in an adjacent group.

8. The method of claim 7, further comprising:
unrolling from the completed roll a portion including at least one group of the groups of photovoltaic cells; and
cutting the portion at a given separating region to separate the portion from the completed roll.

9. The method of claim 7, wherein each group of photovoltaic cells is electrically connected to a plurality of bypass diodes.

10. The method of claim 1, wherein each bypass diode has an anode electrically connected to a cathode of one photovoltaic cell in the string and has a cathode electrically connected to an anode of another photovoltaic cell in the string.

11. A system comprising:
a fabrication apparatus configured to:
incrementally form a string of photovoltaic cells such that the photovoltaic cells in the string extend from a leading edge of the string, wherein, to incrementally form the string, the fabrication apparatus is configured to sequentially connect successive photovoltaic cells, and wherein, to sequentially connect successive photovoltaic cells, the fabrication apparatus is configured to connect each successive photovoltaic cell to a respective, previously-connected photovoltaic cell that is farthest from the leading edge, and
electrically connect bypass diodes to successive portions of the string as the string is being formed, such that each successive portion includes a bypass diode connected in parallel with a first predetermined number of photovoltaic cells connected in series;
a rolling apparatus configured to:
wind the string with the bypass diodes connected thereto into a roll by rotating the leading edge of the string about a take-up roller as the string is being formed, and
complete the roll in response to the string reaching a second predetermined number of photovoltaic cells; and
a vacuum sealing apparatus configured to seal the completed roll within a moisture barrier.

12. The system of claim 11, wherein the string of photovoltaic cells comprises groups of photovoltaic cells separated by respective separating regions, wherein the photovoltaic cells are electrically connected in series within each group, and wherein each separating region electrically isolates the photovoltaic cells in one group from the photovoltaic cells in an adjacent group.

13. The system of claim 12, wherein each group of photovoltaic cells has a third predetermined number of photovoltaic cells, and wherein each group of photovoltaic cells is electrically connected to a plurality of bypass diodes.

14. A package, comprising:
a roll of photovoltaic cells, wherein the roll of photovoltaic cells comprises a string of photovoltaic cells wound around a core of the roll, wherein the string of photovoltaic cells comprises groups of photovoltaic cells separated by respective separating regions,
wherein each group comprises a predetermined number of photovoltaic cells connected in series, and wherein each separating region electrically isolates the photovoltaic cells in one group from the photovoltaic cells in an adjacent group;
wherein each group is electrically connected to one or more bypass diodes, such that each of the one or more bypass diodes is connected in parallel to a respective set of one or more photovoltaic cells in the group; and
packaging that at least partially surrounds the roll of photovoltaic cells.

15. The package of claim 14, wherein the packaging comprises a moisture barrier vacuum sealed around the roll of photovoltaic cells.
